(19) United States
(12) Patent Application Publication
(10) Pub. No.: US 2023/0028460 A1
(43) Pub. Date: Jan. 26, 2023

(54) Forming Silicon-Containing Material Over Metal Gate To Reduce Loading Between Long Channel And Short Channel Transistors

(71) Applicant: Taiwan Semiconductor Manufacturing Company, Ltd., Hsin-Chu (TW)

(72) Inventors: Wei-Cheng Wang, Hsinchu (TW); Shih-Hang Chiu, Taichung City (TW); Kuan-Ting Liu, Hsinchu City (TW); Cheng-Lung Hung, Hsinchu City (TW); Chi On Chui, Hsinchu City (TW)

(21) Appl. No.: 17/725,722

(22) Filed: Apr. 21, 2022

Related U.S. Application Data
(60) Provisional application No. 63/224,926, filed on Jul. 23, 2021.

(51) Int. Cl. H01L 23/535; H01L 27/088; H01L 23/532; H01L 21/768; H01L 21/8234

(52) U.S. Cl. CPC H01L 23/535; H01L 27/0886; H01L 23/53257; H01L 21/76805; H01L 21/76895; H01L 21/823431; H01L 21/823475

(57) ABSTRACT

A semiconductor device includes an active region. A metal gate electrode is disposed over the active region. A conductive layer is disposed over the metal gate electrode. A silicon-containing layer is disposed over a first portion of the conductive layer. A dielectric layer is disposed over a second portion of the conductive layer. A gate via vertically extends through the silicon-containing layer. The gate via is disposed over, and electrically coupled to, the metal gate electrode.

### PRIORITY DATA

The present application is a utility U.S. patent application of provisional U.S. Patent Application No. 63/224,926, filed on Jul. 23, 2021, entitled “GATE ELECTRODE HAVING A SILICON-BASED MATERIAL”, the disclosure of which is hereby incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as the sizes of the transistor components continue to get smaller, loading effects caused by the size differences between long channel transistors and short channel transistors may become more pronounced. As a result, device performance may be degraded.

Therefore, although existing semiconductor devices have been generally adequate for their intended purposes, they have not been entirely satisfactory in every aspect.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. It is also emphasized that the drawings appended illustrate only typical embodiments of this invention and are therefore not to be considered limiting in scope, for the invention may apply equally well to other embodiments.

FIG. 1A illustrates a three-dimensional perspective view of a FinFET device.

FIG. 1B illustrates a top view of a FinFET device.

FIG. 1C illustrates a three-dimensional perspective view of a multi-channel gate-all-around (GAA) device.

FIGS. 2-12 illustrate a series of cross-sectional views of a semiconductor device at various stages of fabrication according to embodiments of the present disclosure.

FIG. 13 illustrates a Static Random Access Memory (SRAM) cell according to various aspects of the present disclosure.

FIG. 14 illustrates an integrated circuit fabrication system according to various aspects of the present disclosure.

FIG. 15 is a flowchart illustrating a method of fabricating a semiconductor device according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Still further, when a number or a range of numbers is described with “about,” “approximate,” and the like, the term is intended to encompass numbers that are within a reasonable range including the number described, such as within +/−10% of the number described or other values as understood by person skilled in the art. For example, the term “about 5 nm” encompasses the dimension range from 4.5 nm to 5.5 nm.

The present disclosure is generally related to semiconductor devices, which may be fabricated using field-effect transistors (FETs) such as three-dimensional fin-line FETs (FinFETs) or multi-channel gate-all-around (GAA) devices. FinFET devices have semiconductor fin structures that protrude vertically out of a substrate. The fin structures are active regions, from which source/drain regions and/or channel regions are formed. The gate structures partially wrap around the fin structures. GAA devices have multiple elongated nano-structure channels that may be implemented as nano-tubes, nano-sheets, or nanowires. In recent years, FinFET devices and GAA devices have gained popularity due to their enhanced performance compared to conventional planar transistors.

However, as semiconductor device sizes continue to get scaled down, conventional methods of fabricating FinFETs or GAA devices may face various challenges. For example, long channel transistors and short channel transistors may be formed on the same wafer, where the long channel transistors have longer channels than the short channel transistors. During the fabrication of the long channel transistors and short channel transistors, one or more etching processes may be performed. For example, the metal gate electrodes of both the long channel transistors and short channel transistors may be etched back to reduce their height. However, as semiconductor devices continue to get scaled down, a loading effect attributed to the size difference between the long channel transistor and short channel transistors may cause the metal gate electrode of the long channel transistor to not be etched as deeply as the metal gate electrode of the short channel transistor. As a result, the metal gate electrode of the long channel transistor may be substantially taller than the metal gate electrode of the short channel transistor. Such a height discrepancy between the metal gate electrodes of long channel and short channel transistors may degrade device performance, lower device yield, and/or even cause device failures.

To address the problem discussed above, the present disclosure implements a unique fabrication process flow, in which a silicon-containing material is formed over a portion of the metal gate electrode of the long channel transistor, but not over the metal gate electrode of the short channel transistor. Due to the presence of the silicon-containing material, the remaining amount of metal gate electrode of the long channel transistor to be etched during the metal gate etch back process is not substantially different than the amount of metal gate electrode of the short channel transistor. As such, the loading effect between the long channel and short channel transistors is substantially alleviated, and the metal gate electrodes of the long channel transistors and short channel transistors can achieve substantially similar heights after their metal gate electrodes are etched back. The present disclosure also deposits a tungsten-containing conductive layer (which has low resistivity) over the metal gate of the long channel transistors both before and after the formation of the silicon-containing material. Such a tungsten-containing conductive layer helps to reduce the resistance of the metal gate, since a gate via will be formed on the tungsten-containing conductive layer. In other words, the tungsten-containing conductive layer serves as the interface between the metal gate electrode and the gate via in order to reduce gate resistance. As such, the present disclosure may simultaneously achieve improved electrical performance (e.g., low resistivity) and device uniformity between transistors of difference sizes.

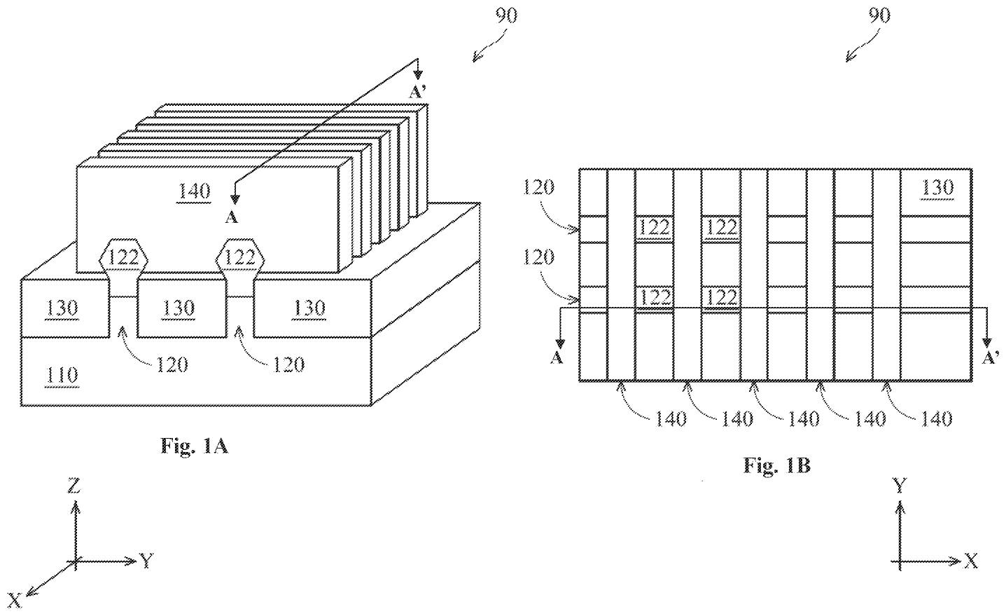

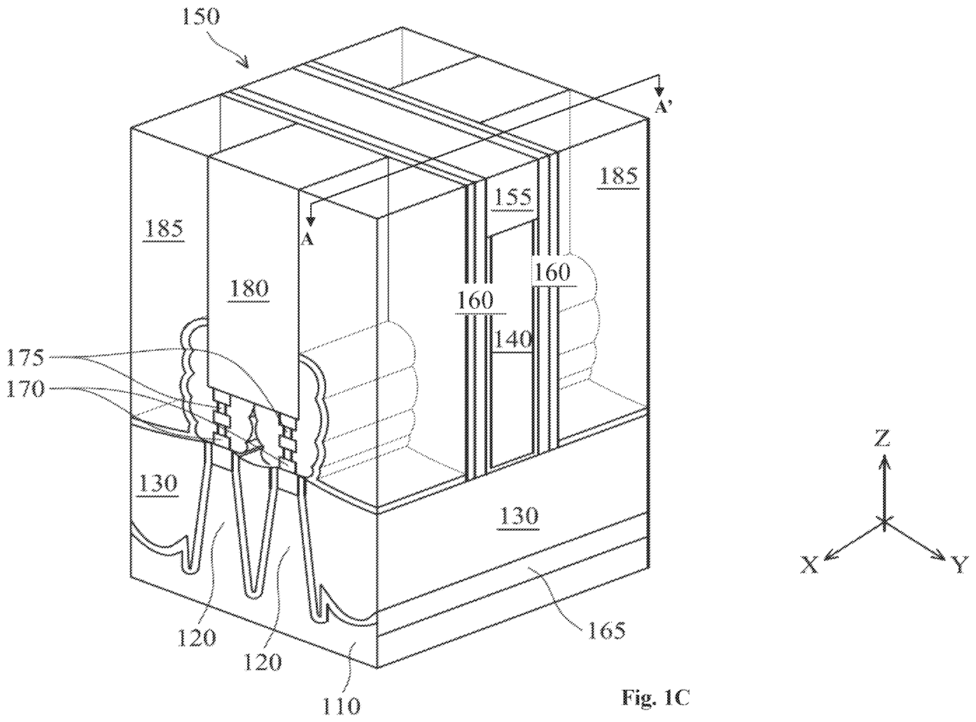

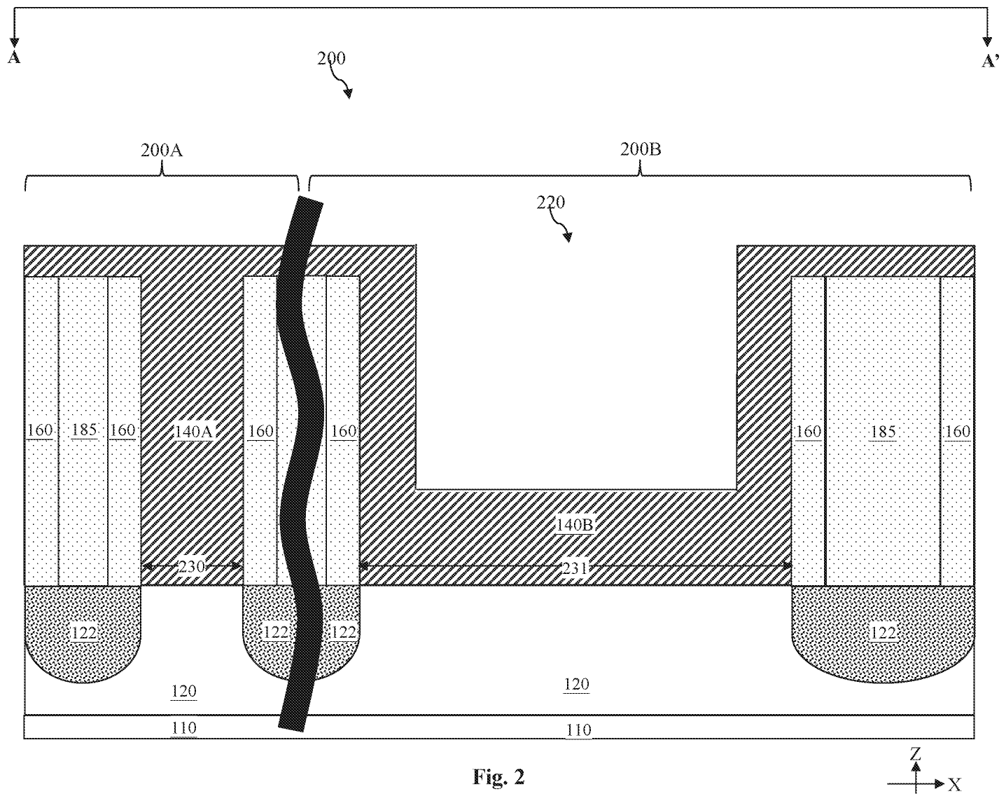

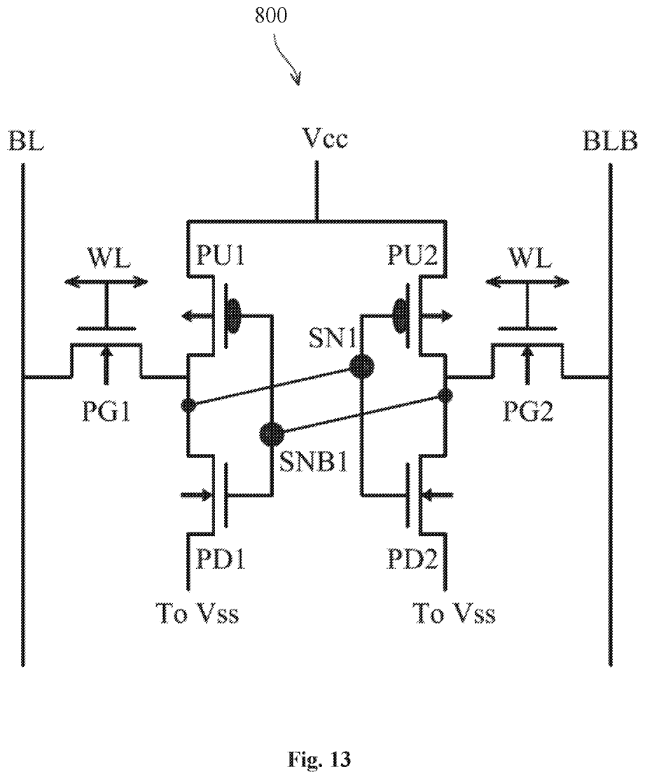

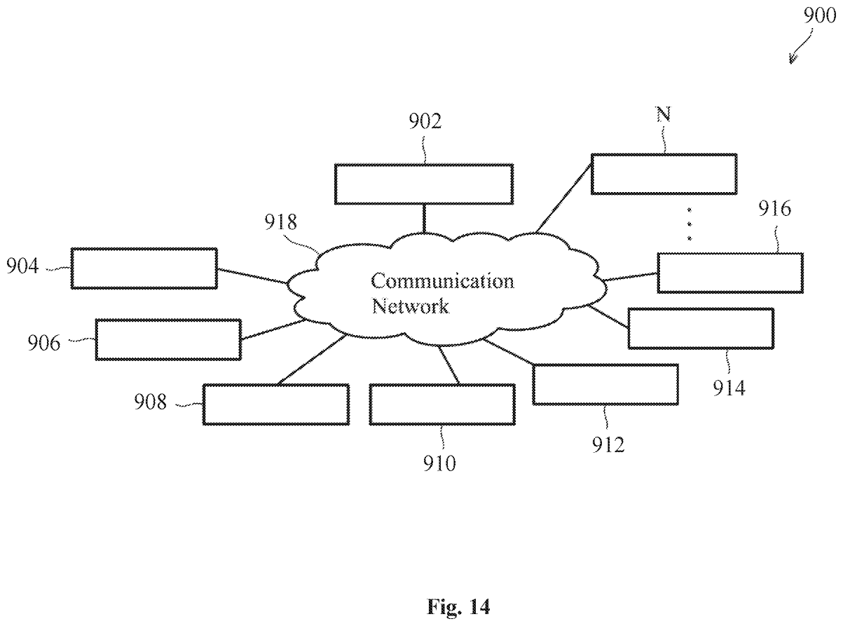

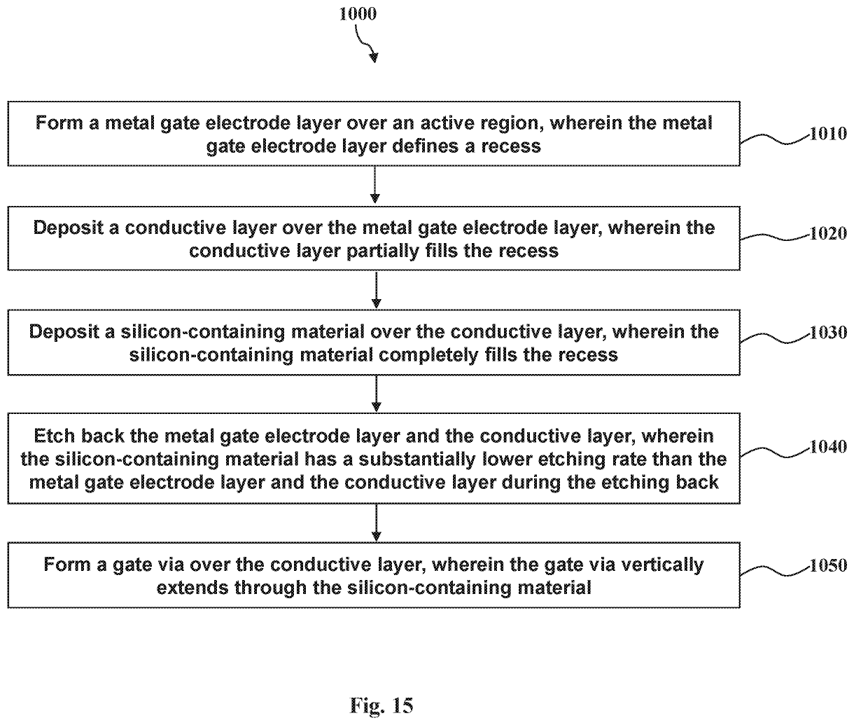

The various aspects of the present disclosure will now be discussed below with reference to FIGS. 1A-1C and 2-15. In more detail, FIGS. 1A-B illustrate an example FinFET device, and FIG. 1C illustrates an example GAA device. FIGS. 2-12 illustrate cross-sectional side views of an IC device at various stages of fabrication according to embodiments of the present disclosure. FIG. 13 illustrates a memory circuit as an example IC application implemented using IC devices fabricated according to the various aspects of the present disclosure. FIG. 14 illustrates a semiconductor fabrication system. FIG. 15 each illustrate a flowchart of a method of fabricating an IC device according to various aspects of the present disclosure.

Referring now to FIGS. 1A and 1B, a three-dimensional perspective view and a top view of a portion of an Integrated Circuit (IC) device 90 are illustrated, respectively. The IC device 90 is implemented using FinFETs. As shown in FIG. 1A, the IC device 90 includes a substrate 110. The substrate 110 may comprise an elementary (single element) semiconductor, such as silicon, germanium, and/or other suitable materials; a compound semiconductor, such as silicon carbide, gallium arsenic, gallium phosphide, indium phosphide, indium arsenide, indium antimonide, and/or other suitable materials; an alloy semiconductor such as SiGe, GaAsP, AlInAs, AlGaAs, GaInAs, GaInP, GaInAsP, and/or other suitable materials. The substrate 110 may be a single-layer material having a uniform composition. Alternatively, the substrate 110 may include multiple material layers having similar or different compositions suitable for IC device manufacturing. In one example, the substrate 110 may be a silicon-on-insulator (SOI)h substrate having a semiconductor silicon layer formed on a silicon oxide layer. In another example, the substrate 110 may include a conductive layer, a semiconductor layer, a dielectric layer, other layers, or combinations thereof. Various doped regions, such as source/drain regions, may be formed in or on the substrate 110. The doped regions may be doped with n-type dopants, such as phosphorus or arsenic, and/or p-type dopants, such as boron, depending on design requirements. The doped regions may be formed directly on the substrate 110, in a p-well structure, in an n-well structure, in a dual-well structure, or using a raised structure. Doped regions may be formed by implantation of dopant atoms, in-situ doped epitaxial growth, and/or other suitable techniques.

Three-dimensional active regions 120 are formed on the substrate 110. The active regions 120 may include elongated fin-like structures that protrude upwardly out of the substrate 110. As such, the active regions 120 may be interchangeably referred to as fin structures 120 or fins 120 hereinafter. The fin structures 120 may be fabricated using suitable processes including photolithography and etch processes. The photolithography process may include forming a photoresist layer overlying the substrate 110, exposing the photoresist to a pattern, performing post-exposure bake processes, and developing the photoresist to form a masking element (not shown) including the resist. The masking element is then used for etching recesses into the substrate 110, leaving the fin structures 120 on the substrate 110. The etching process may include dry etching, wet etching, reactive ion etching (RIE), and/or other suitable processes. In some embodiments, the fin structure 120 may be formed by double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. As an example, a layer may be formed over a substrate and patterned using a photolithography process. Spacers are formed alongside the patterned layer using a self-aligned process. The layer is then removed, and the remaining spacers, or mandrels, may then be used to pattern the fin structures 120.

The IC device 90 also includes source/drain components 122 formed over the fin structures 120. The source/drain components 122 may include epi-layers that are epitaxially grown on the fin structures 120. The IC device 90 further includes isolation structures 130 formed over the substrate 110. The isolation structures 130 electrically separate various components of the IC device 90. The isolation structures 130 may include silicon oxide, silicon nitride, silicon oxynitride, fluoride-doped silicate glass (FSG), a low-k dielectric material, and/or other suitable materials. In some embodiments, the isolation structures 130 may include shallow trench isolation (STI) features. In one embodiment, the isolation structures 130 are formed by etching trenches in the substrate 110 during the formation of the fin structures 120. The trenches may then be filled with an isolating material described above, followed by a chemical mechanical planarization (CMP) process. Other isolation structure such as field oxide, local oxidation of silicon (LOCOS), and/or other suitable structures may also be implemented as the isolation structures 130. Alternatively, the isolation structures 130 may include a multi-layer structure, for example, having one or more thermal oxide liner layers.

The IC device 90 also includes gate structures 140 formed over and engaging the fin structures 120 on three sides in a channel region of each fin 120. In other words, the gate structures 140 each wrap around a plurality of fin structures 120. The gate structures 140 may be dummy gate structures (e.g., containing an oxide gate dielectric and a polysilicon gate electrode), or they may be High-k metal gate (HKMG) structures that contain a high-k gate dielectric and a metal gate electrode, where the HKMG structures are formed by replacing the dummy gate structures. Though not depicted herein, the gate structure 140 may include additional material layers, such as an interfacial layer over the fin structures 120, a capping layer, other suitable layers, or combinations thereof.

Referring to FIGS. 1A-1B, multiple fin structures 120 are each oriented lengthwise along the X-direction, and multiple gate structure 140 are each oriented lengthwise along the Y-direction, i.e., generally perpendicular to the fin structures 120. In many embodiments, the IC device 90 includes additional features such as gate spacers disposed along sidewalls of the gate structures 140, hard mask layer(s) disposed over the gate structures 140, and numerous other features.

FIG. 1C illustrates a three-dimensional perspective view of an example GAA device 150. For reasons of consistency and clarity, similar components in FIG. 1C and FIGS. 1A-1B will be labeled the same. For example, active regions such as fin structures 120 rise vertically upwards out of the substrate 110 in the Z-direction. The isolation structures 130 provide electrical separation between the fin structures 120. The gate structure 140 is located over the fin structures 120 and over the isolation structures 130. A mask 155 is located over the gate structure 140, and gate spacers 160 are located on sidewalls of the gate structure 140. A capping layer 165 is formed over the fin structures 120 to protect the fin structures 120 from oxidation during the forming of the isolation structures 130.

A plurality of nano-structures 170 is disposed over each of the fin structures 120. The nano-structures 170 may include nano-sheets, nano-tubes, or nano-wires, or some other type of nano-structure that extends horizontally in the X-direction. Portions of the nano-structures 170 under the gate structure 140 may serve as the channels of the GAA device 150. Dielectric inner spacers 175 may be disposed between the nano-structures 170. In addition, although not illustrated for reasons of simplicity, each stack of the nano-structures 170 may be wrapped around circumferentially by a gate dielectric as well as a gate electrode. In the illustrated embodiment, the portions of the nano-structures 170 outside the gate structure 140 may serve as the source/drain features of the GAA device 150. However, in some embodiments, continuous source/drain features may be epitaxially grown over portions of the fin structures 120 outside of the gate structure 140. Regardless, conductive source/drain contacts 180 may be formed over the source/drain features to provide electrical connectivity thereto. An interlayer dielectric (ILD) 185 is formed over the isolation structures 130 and around the gate structure 140 and the source/drain contacts 180. The ILD 185 may be referred to as an ILD0 layer. In some embodiments, the ILD 185 may include silicon oxide, silicon nitride, or a low-k dielectric material.

Additional details pertaining to the fabrication of GAA devices are disclosed in U.S. Pat. No. 10,164,012, titled “Semiconductor Device and Manufacturing Method Thereof” and issued on Dec. 25, 2018, as well as in U.S. Pat. No. 10,361,278, titled “Method of Manufacturing a Semiconductor Device and a Semiconductor Device” and issued on Jul. 23, 2019, and also in U.S. Pat. No. 9,887,269, titled “Multi-Gate Device and Method of Fabrication Thereof” and issued on Feb. 6, 2018, the disclosures of each which are hereby incorporated by reference in their respective entireties. To the extent that the present disclosure refers to a fin structure or FinFET devices, such discussions may apply equally to the GAA devices.

FIGS. 2-12 illustrate diagrammatic fragmentary cross-sectional views of a portion of the IC device 200 at various stages of fabrication according to various embodiments of the present disclosure. Since FIGS. 2-12 illustrate the cross-sectional views along a X-Z plane, and as such, FIGS. 2-12 may be referred to as X-cuts. For example, the cross-sectional side views of the IC device in FIGS. 2-12 may be obtained by taking a cross-sectional cut along the cutline A-A′ shown in FIGS. 1A-1C. For reasons of simplicity and consistency, similar components appearing in FIGS. 1A-1C will be labeled the same in FIGS. 2-12. It is also understood that although the discussions below primarily use a FinFET (e.g., the FinFET of FIGS. 1A-1B) to illustrate the inventive concepts of the present disclosure, the same concepts may apply to the GAA device (e.g., the GAA device of FIG. 1C) as well, unless otherwise noted.

As shown in FIG. 2, the IC device 200 includes a short channel transistor 200A and a long channel transistor 200B. The short channel transistor 200A and 200B are formed on the same wafer, though they may be formed at different regions of the wafer and may not necessarily be physically contiguous to one another. The short channel transistor 200A and the long channel transistor 200B each include the substrate 110 discussed above with reference to FIGS. 1A-1C, for example, a silicon substrate. A plurality of active regions may be formed for the short channel transistor 200A and long channel transistor 200B by patterning the substrate 110. For example, the active regions may include the fin structures 120 discussed above with reference to FIGS. 1A-1B, or the nano-structures 170 discussed above with reference to FIG. 1C. Source/drain components 122 are formed over the active regions for both the short channel transistor 200A and long channel transistor 200B. In some embodiments, the source/drain components 122 may include epi-layers that are epitaxially grown on the active regions.

High-k metal gate (HKMG) structure 140A and 140B are formed for the short channel transistor 200A and long channel transistor 200B, respectively. The HKMG structures 140A and 140B may each include a high-k gate dielectric and a metal-containing gate electrode. The high-k gate dielectric contains a high-k dielectric material, which refers to a dielectric material having a dielectric constant that is greater than a dielectric constant of silicon oxide (e.g., which is about 3.9). Example materials of the high-gate k dielectric include hafnium oxide, zirconium oxide, aluminum oxide, hafnium dioxide-alumina alloy, hafnium silicon oxide, hafnium silicon oxynitride, hafnium tantalum oxide, hafnium titanium oxide, hafnium zirconium oxide, or combinations thereof. The metal-containing gate electrode is formed over the high-k gate dielectric. The metal-containing gate electrode may include one or more work function (WF) metal layers and one or more fill metal layers. The work function metal layers may be configured to tune a work function of the respective transistor. Example materials for the work function metal layers may include titanium nitride (TiN), Titanium aluminide (TiAl), tantalum nitride (TaN), titanium carbide (Tic), tantalum carbide (TaC), tungsten carbide (WC), aluminum titanium nitride (TiAlN), zirconium aluminide (ZrAl), tungsten aluminide (WAl), tantalum aluminide (TaAl), hafnium aluminide (HfAl), or combinations thereof. The fill metal layer may serve as the main conductive portion of the metal-containing gate electrode. In some embodiments, the fill metal layer may include cobalt, tungsten, copper, aluminum, or alloys or combinations thereof. It is understood that each of the HKMG structures may include additional layers, such as interfacial layers, capping layers, diffusion/barrier layers, or other applicable layers.

In some embodiments, each of the HKMG structures 140 is formed using a gate replacement process, in which a dummy gate structure is formed first and subsequently replaced by the HKMG structure. In that regard, the initially-formed dummy gate structure may include a dummy gate dielectric (e.g., a silicon oxide gate dielectric) and a dummy polysilicon gate electrode. Gate spacers 160 and the ILD 185 may be formed around the dummy gate structures. For example, the gate spacers 160 (e.g., containing a dielectric material such as silicon nitride or silicon oxide) may be formed on the sidewalls of the dummy gate structures, and the ILD 185 may be formed around the gate spacers 160. Note that in some embodiments, the gate spacers 160 may include a plurality of gate spacer layers, which may contain different types of dielectric materials. However, for reasons of simplicity, the gate spacers (even if they include different materials) are collectively illustrated as the gate spacers 160 herein. Also note that other layers (such as etching-stop layers) may be formed over the ILD 185 and/or the gate spacers 160. However, these other layers are not specifically illustrated for reasons of simplicity.

After the formation of source/drain components 122, the dummy gate structures are removed (e.g., via one or more etching processes), thereby forming openings or recesses defined at least in part by the gate spacers 160. The HKMG structures 140A and 140B are then formed in the openings to replace the removed dummy gate structures. However, due to the size difference between the short channel transistor 200A and the long channel transistor 200B, the HKMG structure 140A completely fills the opening defined by the removal of the dummy gate structure, while the HKMG structure 140B still defines a recess 220.

In more detail, the short channel transistor 200A has a horizontal dimension 230 measured in the X-direction, whereas the long channel transistor 200B has a horizontal dimension 231 measured in the X-direction. The horizontal dimension 231 is significantly greater than the horizontal dimension 230. For example, whereas the horizontal dimension 230 may be in a range of several nanometers (nm), the horizontal dimension 231 may be in a range of several tens of nanometers. In some embodiments, the horizontal dimension 230 is in a range between about 1 nm and about 5 nm, while the horizontal dimension 231 is in a range between about 30 nm and about 70 nm. In some embodiments, the horizontal dimension 231 is at least ten times greater than the horizontal dimension 230. Note that the horizontal dimensions 230 and 231 also roughly correspond with the channel lengths of the short channel transistor 200A and the long channel transistor 200B. In other words, the channel length of the long channel transistor 200B is substantially longer than the channel length of the short channel transistor 200A (hence their respective “long channel” and “short channel” names).

As shown in FIG. 2, since the horizontal dimension 230 is relatively short, the deposited metal gate electrode materials of the HKMG structure 140A is able to completely fill the opening left behind by the removal of the dummy gate structure. Meanwhile, since the horizontal dimension 231 is relatively long, the deposited metal gate electrode materials of the HKMG structure 140B does not completely fill the opening left behind by the removal of the dummy gate structure and defines the upwardly-facing recess 220 instead. While a conductive material (e.g., tungsten) could be deposited to fill the recess 220 to complete the formation of the metal gate electrode for the long channel transistor 200B, such a simplified solution may lead to loading problems. For example, such a solution would form a substantially bigger (e.g., longer in the X-direction) metal gate electrode for the long channel transistor 200B than for the short channel transistor 200A. When these metal gate electrodes are etched back in a later fabrication process, their size discrepancy would cause the metal gate electrode of the short channel transistor 200A to be etched substantially deeper than the metal gate electrode of the long channel transistor 200B. Consequently, the long channel transistor 200B would have a substantially taller metal gate electrode than the short channel transistor 200A, which could lead to performance degradations, lower yields, or even device failures.

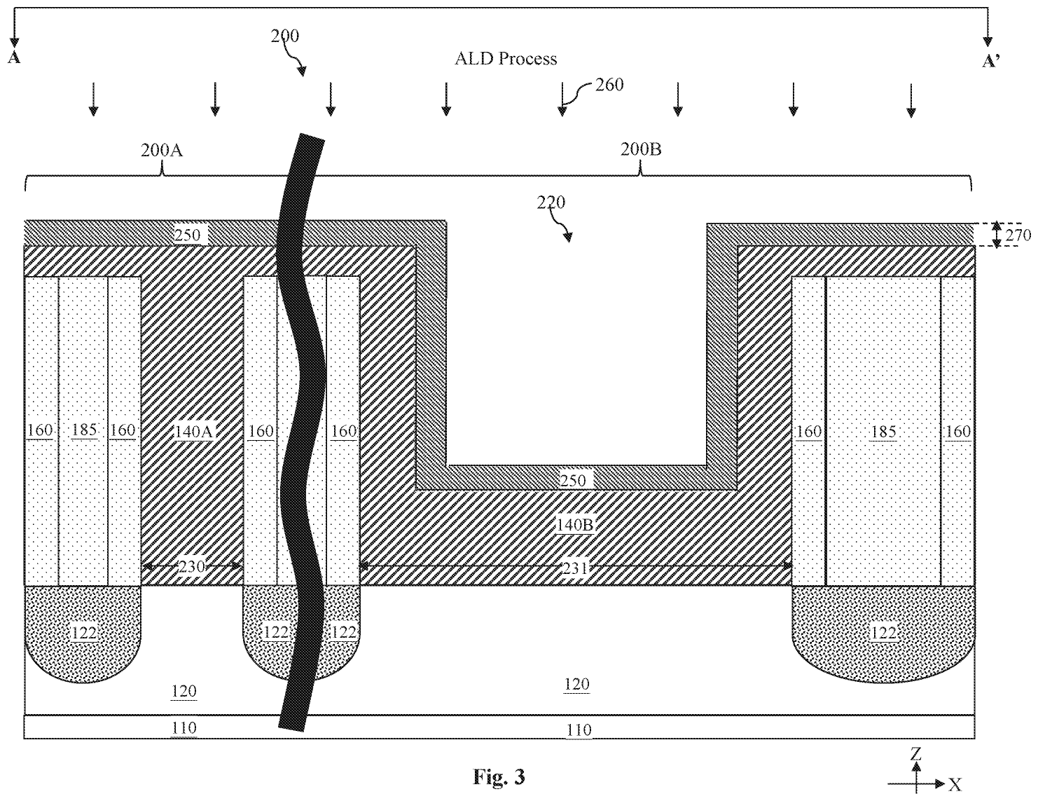

To overcome such a loading problem, the present disclosure first deposits a conductive layer 250 over the HKMG structures 140A and 140B for both the short channel transistor 200A and the long channel transistor 200B, as shown in FIG. 3. In some embodiments, the conductive layer 250 is formed by an atomic layer deposition (ALD) process 260, in which WCl₅ is used as a precursor. The ALD process 260 may be performed with a precursor temperature setting in a range between about 100 degrees Celsius and about 150 degrees Celsius, at a process temperature setting in a range between about 410 degrees Celsius and about 510 degrees Celsius, and with a process pressure in a range between about 10 Torrs and about 50 Torrs. In some embodiments, the ALD process 260 may also be performed using H₂ as a reducing gas, using Ar as a carrier gas, and generates HCl as a byproduct.

As a result of the performance of the ALD process 260, the conductive layer 250 is formed to have a material composition that contains tungsten and chlorine. Such a material composition allows the conductive layer 250 to achieve low resistivity, which will facilitate it serving as a part of an electrical interface between the HKMG structure 140B and a gate via to be formed thereon in a later process. The process parameters of the ALD process 260 are also specifically configured to achieve a thickness 270 for the conductive layer 250. In some embodiments, the thickness 270 is in a range between about 2 nm and about 6 nm. Such a thickness range is not randomly selected but rather specifically chosen to optimize various aspects of the present disclosure. For example, the thickness 270 is thick enough to allow the conductive layer 250 to adequately reduce gate resistance, but not too thick to make its etching thereof difficult, since the conductive layer 250 will be etched in an etch-back process to be performed in a later fabrication process (discussed in greater detail below). Note that the thickness 270 is substantially less than ½ of the horizontal dimension 231, such that the conductive layer 250 only partially (but not completely) fills the recess 220. In other words, the cross-sectional profile in the X-Z plane still substantially preserves the recess 220.

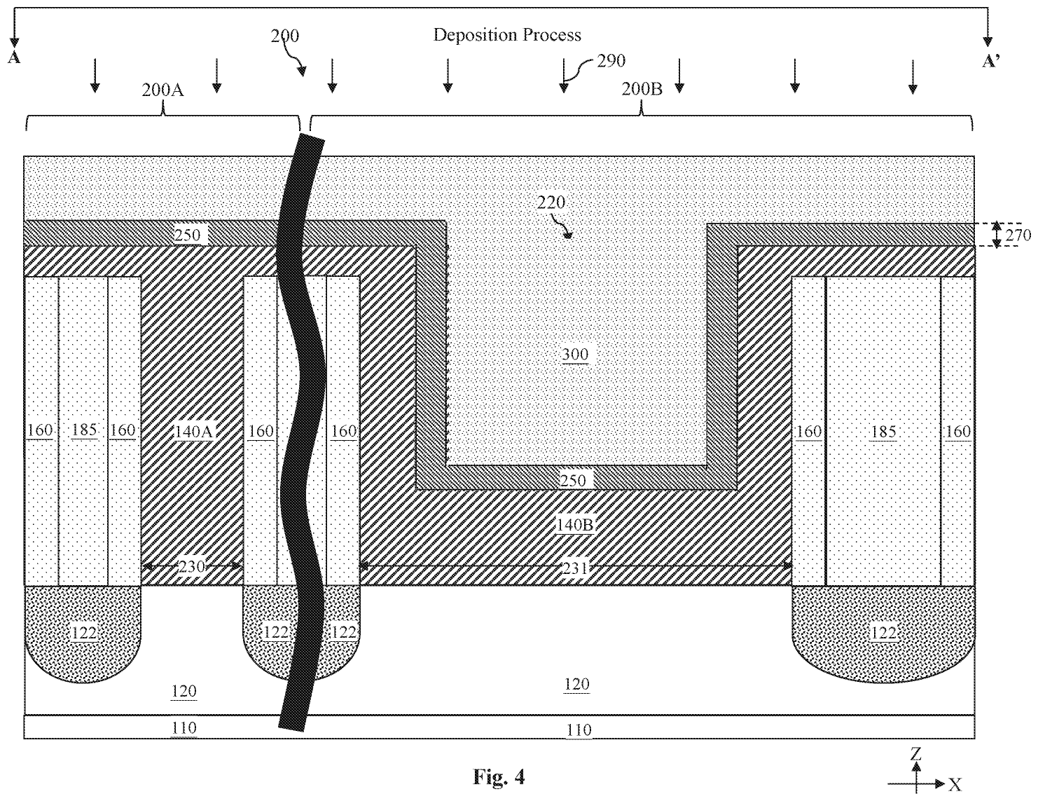

Referring now to FIG. 4, a deposition process 290 is performed to form a silicon-containing material 300 over the conductive layer 250 for both the short channel transistor 200A and the long channel transistor 200B. The deposition process 290 may include a CVD process, a PVD process, an ALD process, or combinations thereof. The deposited silicon-containing material 300 completely fills the recess 220. In some embodiments, the silicon-containing material 300 may include silicon, silicon oxide, silicon nitride, silicon oxynitride, or another silicon-containing dielectric or semiconductive material. As will be discussed in more detail below, the material composition of the silicon-containing material 300 is specifically configured to such that it has a sufficiently high etching selectivity with the materials of the HKMG structure 140B and the conductive layer 250, such that the HKMG structure 140B and the conductive layer 250 may be etched back without substantially affecting the silicon-containing material 300 in a gate etch-back process performed later.

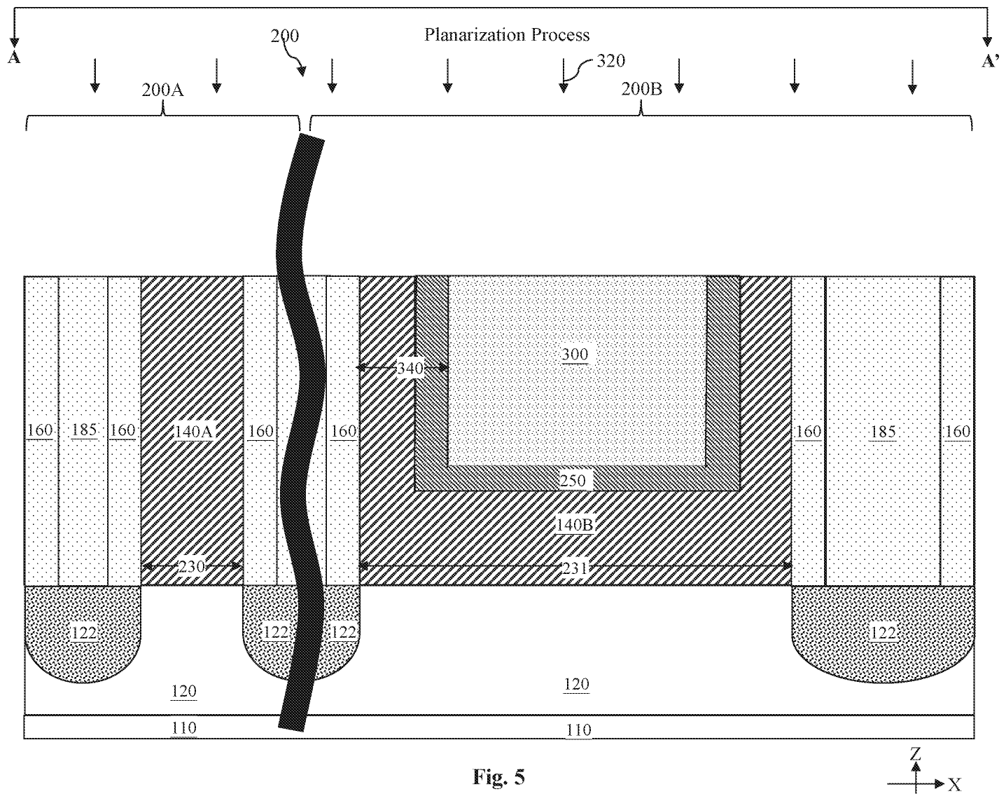

Referring now to FIG. 5, a planarization process 320 is performed to polish and/or grind away portions of the silicon-containing material 30, the conductive layer 250, and the HKMG structures 140A and 140B, until no portions of the HKMG structures 140A or 140B remain over the upper surfaces of the ILD 185 or over the gate spacers 160, and that the upper surfaces of the remaining portions of the silicon-containing material 30, the conductive layer 250, and the HKMG structures 140A and 140B are substantially co-planar with the upper surfaces of the ILD 185 and the gate spacers 160. In some embodiments, the planarization process 320 includes a chemical mechanical polishing (CMP) process.

At this stage of fabrication, a sidewall of the silicon-containing material 300 is spaced apart from its nearest sidewall of the gate spacer 160 by a distance 340 in the X-direction. Due to the presence of the silicon-containing material 300, the distance 340 is substantially smaller than the dimension 231 of the HKMG structure 140B. The value of the distance 340 may be configured by adjusting a lateral size (or width) of the silicon-containing material 300 in the X-direction, which may be done at least in part by configuring the value of the thickness 270 of the conductive layer 250. In order to reduce the loading effect that would otherwise manifest itself during a subsequent etch-back process, the distance 340 is configured to be similar in value to the dimension 230 of the HKMG structure 140A. In some embodiments, a ratio of the distance 340 and the dimension 230 is tuned to be in a range between about 0.6:1 and about 1.7:1. Such a ratio is not randomly selected but rather specifically configured to reduce the loading effects. For example, if the ratio of the distance 340 and the dimension 230 is outside of the above range, the loading effect discussed above may still manifest itself in the etch-back to be performed subsequently, which may degrade device performance or lower yield.

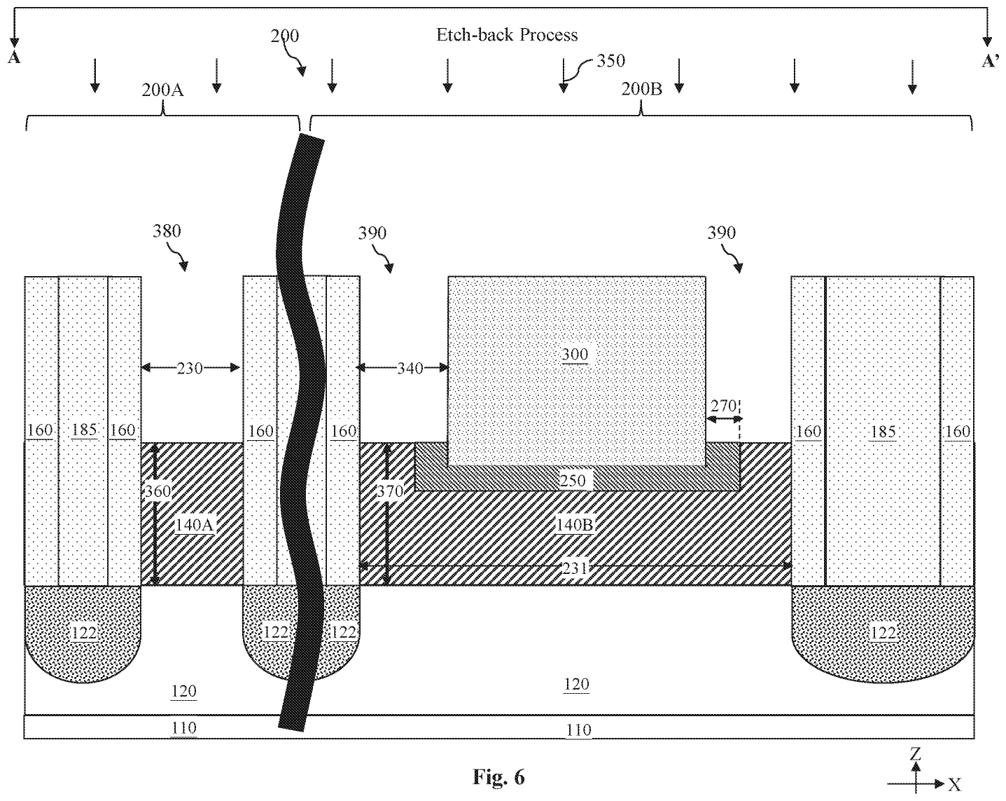

Referring now to FIG. 6, an etch-back process 350 is performed to the short channel transistor 200A and the long channel transistor 200B to partially remove or etch away the HKMG structures 140A and 140B to reduce the heights thereof. Note that the conductive layer 250 is also etched back at a substantially similar rate as the HKMG structure 140B, since the both contain metal. However, due to the material composition of the silicon-containing material 300 being substantially different than that of the HKMG structure 140B or the conductive layer 250, the etch-back process 350 may be configured to have a sufficiently high etching selectivity between the silicon-containing material 300 and the HKMG structure 140B and the conductive layer 250. In other words, the silicon-containing material 300 has a substantially slower etching rate (e.g., at least ten times slower) than the HKMG structure 140B or the conductive layer 250 during the etch-back process 350, such that the removal (i.e., the etching back) of the HKMG 140B and the conductive layer 250 does not substantially reduce the height of the silicon-containing material 300 (or at least to a much lesser extent). Similarly, the isolation structures 185 and the gate spacers 160 may also be substantially unaffected by the etch-back process 350, since their material compositions allow them to achieve a high etching-selectivity with the HKMG structures 140A-140B and the conductive layer 250 as well.

As discussed above, since the distance 340 is similar to the dimension 230 of the HKMG structure 140A in value, the lateral dimensions of the materials to be etched back during the etch-back process 350 are similar for the short channel transistor 200A and the long channel transistor 200B. In contrast, conventional methods of semiconductor fabrication would have to etch a much wider HKMG structure for the long channel transistor and a much narrower HKMG structure for the short channel transistor, which would have exhibited a loading effect that causes the remaining portion of the HKMG structure of the long channel transistor to be much taller than the HKMG structure of the short channel transistor.

Here, by implementing the silicon-containing material 300, the HKMG structure 140B (and the conductive layer 250) of the long channel transistor 200B is similar in lateral dimension as the short channel transistor 200A (e.g., the distance 340 vs the dimension 230). Consequently, the loading effect is substantially reduced, and a height 360 of the remaining portion of the HKMG structure 140A of the short channel transistor 200A is substantially similar in value to a height 370 of the remaining portion of the HKMG structure 140B of the long channel transistor 200B. Stated differently, the upper surfaces of the HKMG structures 140A and 140B have substantially similar vertical elevations (in the Z-direction) after the etch-back process 350 is performed. In some embodiments, a ratio of the height 360 and the height 370 may be in a range between about 0.9:1 and about 1.1:1. Again, such a similar in heights between the remaining portions of the HKMG structures 140A and 140B is made possible due to the reduction in loading.

As shown in FIG. 6, the partial removal of the HKMG structures 140A-140B and the conductive layer 250 result in the formation of recesses 380 and 390 for the short channel transistor 200A and long channel transistor 200B, respectively. The recess 380 is defined by the HKMG structure 140A and the gate spacers 160 of the short channel transistor 200A, and the recess 380 is defined by the HKMG structure 140B, the gate spacers 160 of the long channel transistor 200B, and the silicon-containing material 300. The recess 370 substantially inherits the lateral dimension 230 of the HKMG structure 140A as its lateral dimension, while the recess 390 substantially inherits the distance 340 as its lateral dimension.

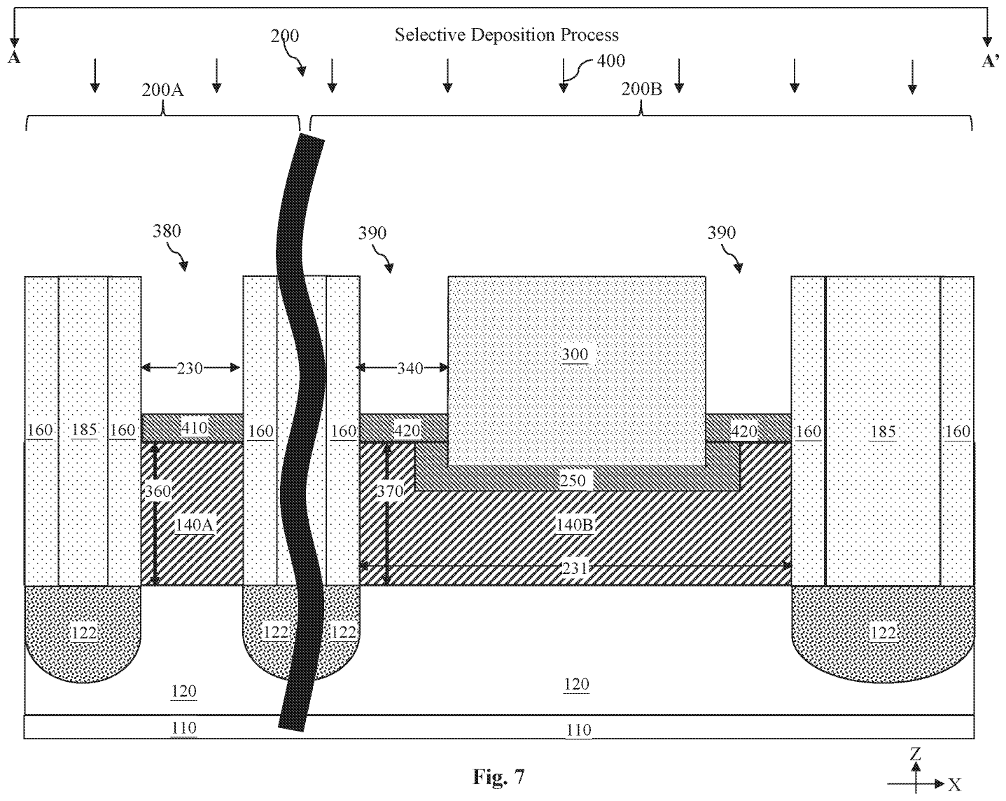

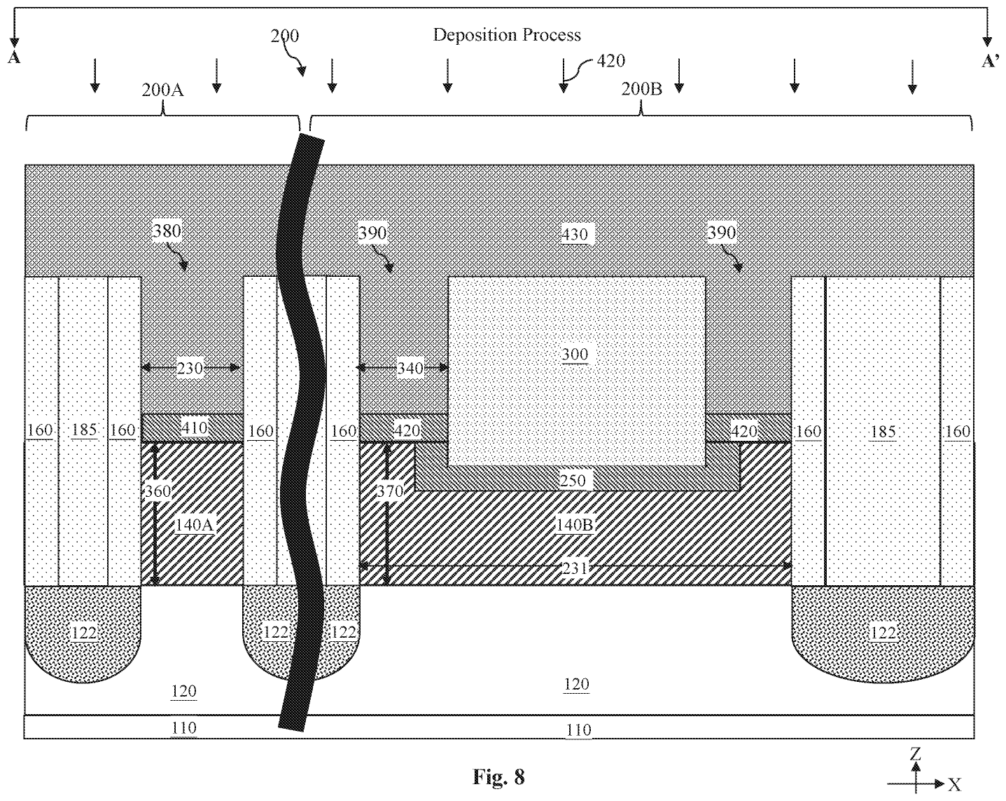

Referring now to FIG. 7, a selective deposition process 400 is performed to simultaneously form a conductive layer 410 for the short channel transistor 200A and a conductive layer 420 for the long channel transistor 200B. Note that the selective deposition process 400 is configured such that the conductive layers 410 and 420 are deposited on metal or metal-like surfaces, but not directly on dielectric surfaces. As such, the conductive layer 410 is selectively formed on the upper (and exposed) surface of the HKMG structure 140A, and the conductive layer 420 is selectively formed on the upper (and exposed) surfaces of the HKMG structure 140B and the conductive layer 250. However, neither of the conductive layers 410 and 420 are formed on the entire sidewalls or upper surfaces of: the gate spacers 160, the ILD 185, or the silicon-containing material 300, which have dielectric material compositions. Similar to the conductive layer 250, the conductive layers 410 and 420 have a low resistivity, which help to reduce the electrical resistance of the HKMG structures 140A and 140B over which they are formed.

In some embodiments, the conductive layers 410 and 420 have a same (or substantially similar) material composition as the conductive layer 250. For example, the conductive layers 410-420 and 250 may each have a material composition that contains tungsten and chlorine (e.g., WCl₅). As such, the conductive layers 420 and 250 may be viewed as two different portions/segments of a same conductive layer: the conductive layer 250 may be viewed as a first portion/segment of such a conductive layer (which is located within the upwardly facing recess defined by the HKMG structure 140B), and the conductive layer 420 may be viewed as a second portion/segment of such a conductive layer (which is located outside of the recess defined by the HKMG structure 140B).

It is noted that, as a result of the unique fabrication process flow of the present disclosure, the HKMG structures 140A and 140B may have different cross-sectional profiles, other than their difference in lateral sizes. For example, the HKMG structure 140B may have a more recessed upper surface than the HKMG structure 140A, since the upper surface of the HKMG structure 140B contains or defines the recess in which the conductive layer 250 is formed. Alternatively, it may be said that the conductive layer collectively formed by the conductive layers 250 and 420 is more recessed than the conductive layer 410, since the conductive layers 250-420 and 410 inherit the recessed profile of the HKMG structures 140B and 140A on which they are formed, respectively.

Referring now to FIG. 8, a deposition process 420 is performed to form a dielectric layer 430 over the conductive layers 410-420, the silicon-containing material 300, the ILD 185, and the gate spacers 160. In some embodiments, the deposition process 420 includes a CVD process, a PVD process, an ALD process, or combinations thereof. The dielectric layer 430 is deposited to completely fill the recesses 380 and 390. In some embodiments, the dielectric layer 430 includes silicon nitride. In other embodiments, the dielectric layer 430 may include a different type of dielectric material. In some embodiments, the dielectric layer 430 has a different material composition than the silicon-containing material 300. For example, in embodiments where the dielectric layer 430 has a silicon nitride material composition, the silicon-containing material 300 may have a non-silicon-nitride material composition, such as a silicon material composition, or a silicon oxide material composition, etc.

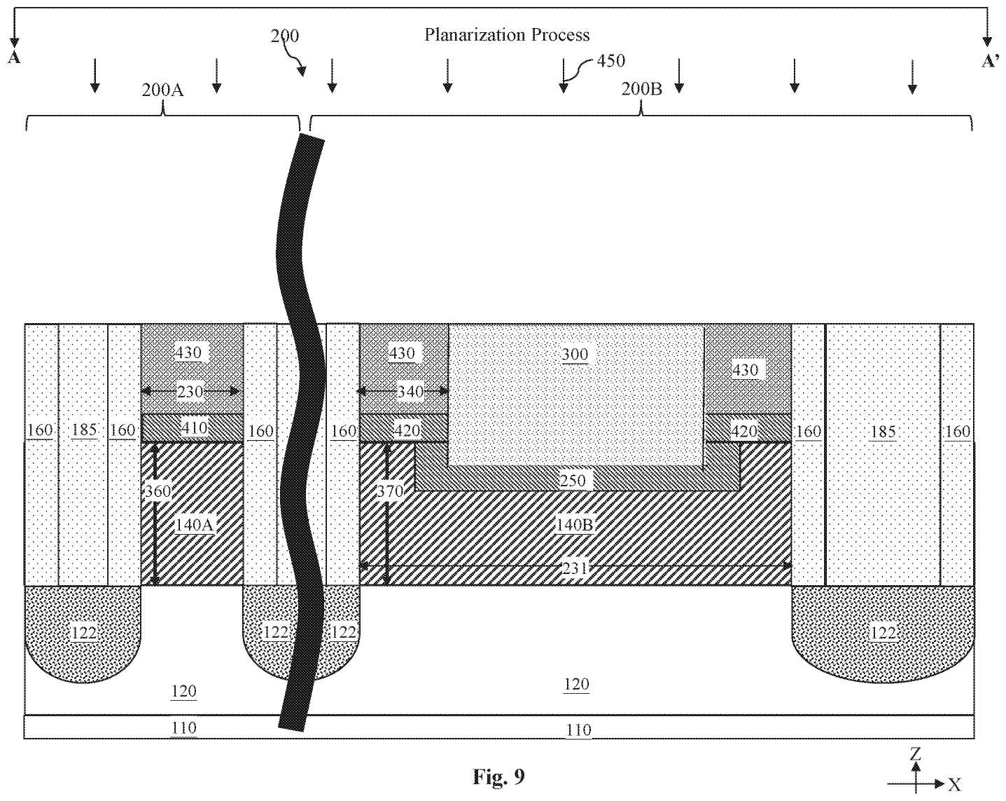

Referring now to FIG. 9, a planarization process 450 is performed to polish and/or grind away portions of the dielectric layer 430, the silicon-containing material 300, the gate spacers 160, and the ILD 185 (or an etching-stop layer formed on the ILD 185 that is not specifically illustrated herein), such that the remain portions thereof have substantially co-planar upper surfaces. In some embodiments, the planarization process 320 includes a chemical mechanical polishing (CMP) process. Note that the material composition of the silicon-containing material 300 is chosen to facilitate the planarization process 450. For example, one reason that the silicon-containing material 300 contains silicon is that the other others to be polished during the planarization process 450 may also contain silicon (e.g., silicon nitride or silicon oxide). As such, the collective polishing of these other layers (along with the silicon-containing material 300) is made easier by ensuring that the silicon-containing material 300 does indeed contain the common element of silicon among all these layers.

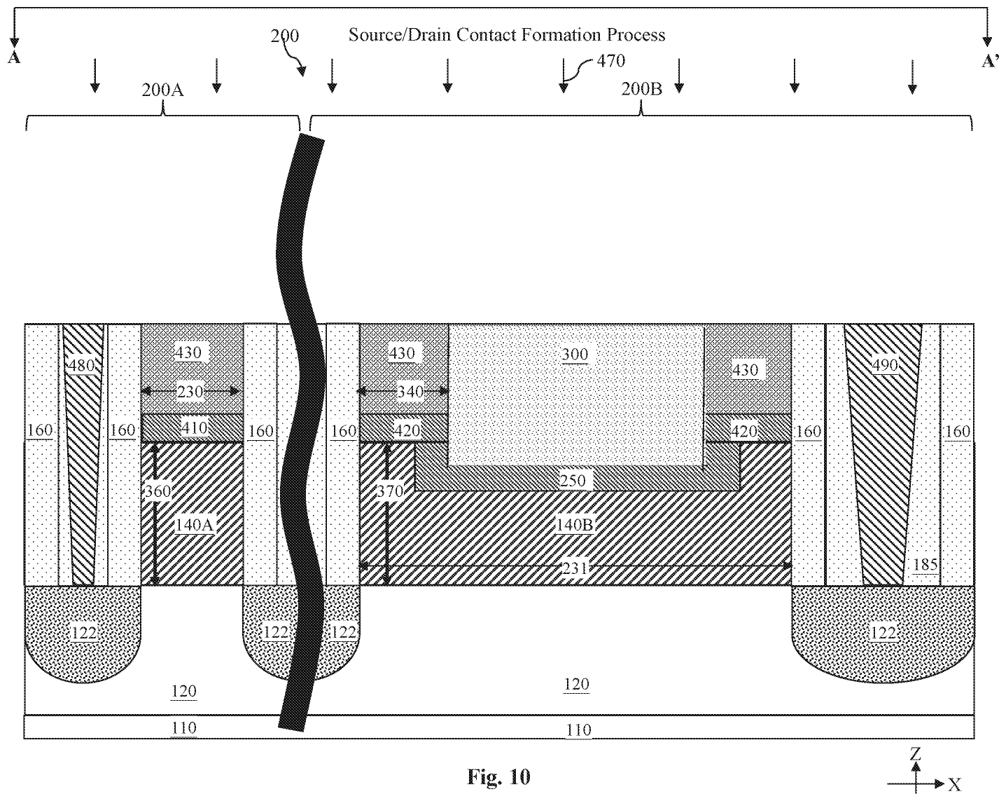

Referring now to FIG. 10, a source/drain contact formation process 470 is performed to form source/drain contacts for both the short channel transistor 200A and the long channel transistor 200B. For example, a source/drain contact 480 may be formed for the short channel transistor 200A, and a source/drain contact 490 may be formed for the long channel transistor 200B. The source/drain contacts 480 and 490 are formed over their respective source/drain components 122 (to provide electrical connectivity thereto) and each vertically extend through the ILD 185. In some embodiments, the source/drain contact formation process 470 may include etching openings or trenches through the ILD 185 to expose the desired regions of the source/drain components 122 therebelow, filling the etched openings or trenches with a conductive material (e.g., cobalt, tungsten, copper, aluminum, titanium, or combinations thereof), and then performing a CMP process to remove excess portions of the conductive material deposited outside of the openings and planarize the upper surfaces of the deposited conductive materials with the rest of the layers such as the silicon-containing material 300, the dielectric layer 430, and the ILD 185.

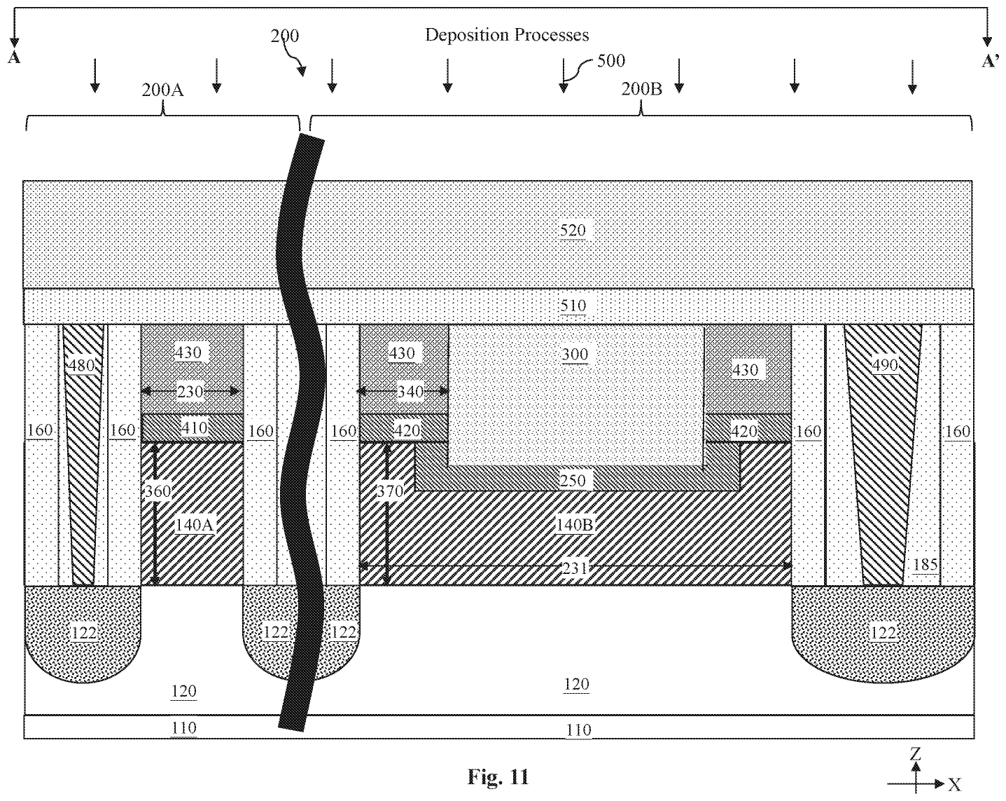

Referring now to FIG. 11, deposition processes 500 are performed to deposit a dielectric layer 510 over the upper surfaces of the ILD 185, the gate spacers 160, the silicon-containing material 300, the dielectric layer 430, and the source/drain contacts 480-490, as well as to deposit a dielectric layer 520 over the upper surface of the dielectric layer 510. In some embodiments, the deposition processes 500 may include CVD, PVD, ALD, or combinations thereof. In some embodiments, the dielectric layer 510 contains silicon nitride, and the dielectric layer 520 contain silicon oxide.

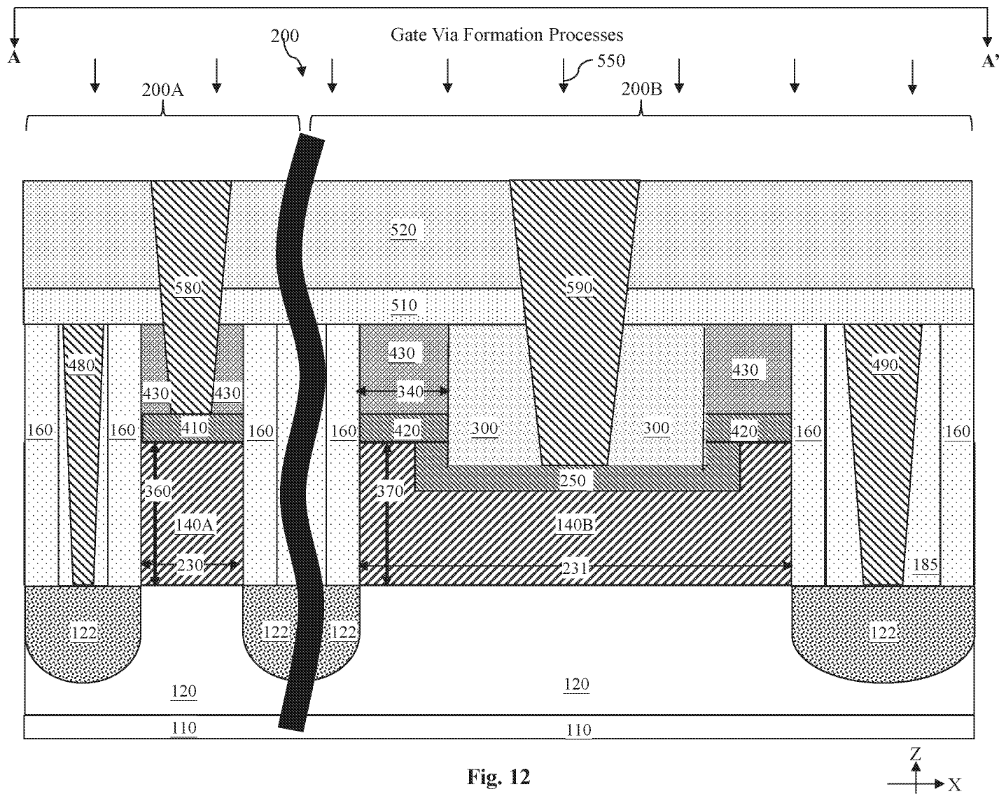

Referring now to FIG. 12, a gate via formation process 550 is performed to form gate vias for both the short channel transistor 200A and the long channel transistor 200B. For example, a gate via 580 may be formed for the short channel transistor 200A, and a gate via 590 may be formed for the long channel transistor 200B. The gate via 580 is formed over the conductive layer 410 to provide electrical connectivity to the HKMG structure 140A. The gate via 590 is formed over the conductive layer 250 to provide electrical connectivity to the HKMG structure 140B.

In some embodiments, the gate via formation process 550 may include etching openings or trenches through the dielectric layers 520 and 510, and the dielectric layer 430 (in the case of the gate via 580) and the silicon-containing material 300 (in the case of the gate via 590) to expose the desired regions of the conductive layers 410 and 250 therebelow, filling the etched openings or trenches with a conductive material (e.g., cobalt, tungsten, copper, aluminum, titanium, or combinations thereof), and then performing a CMP process to remove excess portions of the conductive material deposited outside of the openings and planarize the upper surfaces of the deposited conductive materials with the dielectric layer 520. Note that due to the implementation of the silicon-containing material 300, the gate via 590 of the long channel transistor 200B vertically extends through the silicon-containing material 300, rather than through the dielectric layer 430 (as is the case for the gate via 580 of the short channel transistor 200A).

It is understood that the IC device 200 discussed above may be implemented in a variety of IC applications, including memory devices such as Static Random-Access Memory (SRAM) devices. In that regard, FIG. 13 illustrates an example circuit schematic for a single-port SRAM cell (e.g., 1-bit SRAM cell) 800. The single-port SRAM cell 800 includes pull-up transistors PU1, PU2; pull-down transistors PD1, PD2; and pass-gate transistors PG1, PG2. As show in the circuit diagram, transistors PU1 and PU2 are p-type transistors, and transistors PG1, PG2, PD1, and PD2 are n-type transistors. According to the various aspects of the present disclosure, the PG1, PG2, PD1, and PD2 transistors are implemented with thinner spacers than the PU1 and PU2 transistors. Since the SRAM cell 800 includes six transistors in the illustrated embodiment, it may also be referred to as a 6T SRAM cell.

The drains of pull-up transistor PU1 and pull-down transistor PD1 are coupled together, and the drains of pull-up transistor PU2 and pull-down transistor PD2 are coupled together. Transistors PU1 and PD1 are cross-coupled with transistors PU2 and PD2 to form a first data latch. The gates of transistors PU2 and PD2 are coupled together and to the drains of transistors PU1 and PD1 to form a first storage node SN1, and the gates of transistors PU1 and PD1 are coupled together and to the drains of transistors PU2 and PD2 to form a complementary first storage node SNB1. Sources of the pull-up transistors PU1 and PU2 are coupled to power voltage Vcc (also referred to as Vdd), and the sources of the pull-down transistors PD1 and PD2 are coupled to a voltage Vss, which may be an electrical ground in some embodiments.

The first storage node SN1 of the first data latch is coupled to bit line BL through pass-gate transistor PG1, and the complementary first storage node SNB1 is coupled to complementary bit line BLB through pass-gate transistor PG2. The first storage node N1 and the complementary first storage node SNB1 are complementary nodes that are often at opposite logic levels (logic high or logic low). Gates of pass-gate transistors PG1 and PG2 are coupled to a word line WL. SRAM devices such as the SRAM cell 800 may be implemented using “planar” transistor devices, with FinFET devices, and/or with GAA devices.

FIG. 14 illustrates an integrated circuit fabrication system 900 according to embodiments of the present disclosure. The fabrication system 900 includes a plurality of entities 902, 904, 906, 908, 910, 912, 914, 916 . . . , N that are connected by a communications network 918. The network 918 may be a single network or may be a variety of different networks, such as an intranet and the Internet, and may include both wire line and wireless communication channels.

In an embodiment, the entity 902 represents a service system for manufacturing collaboration; the entity 904 represents an user, such as product engineer monitoring the interested products; the entity 906 represents an engineer, such as a processing engineer to control process and the relevant recipes, or an equipment engineer to monitor or tune the conditions and setting of the processing tools; the entity 908 represents a metrology tool for IC testing and measurement; the entity 910 represents a semiconductor processing tool, such the processing tools to perform the deposition processes 560, 590, or 620 discussed above; the entity 912 represents a virtual metrology module associated with the processing tool 910; the entity 914 represents an advanced processing control module associated with the processing tool 910 and additionally other processing tools; and the entity 916 represents a sampling module associated with the processing tool 910.

Each entity may interact with other entities and may provide integrated circuit fabrication, processing control, and/or calculating capability to and/or receive such capabilities from the other entities. Each entity may also include one or more computer systems for performing calculations and carrying out automations. For example, the advanced processing control module of the entity 914 may include a plurality of computer hardware having software instructions encoded therein. The computer hardware may include hard drives, flash drives, CD-ROMs, RAM memory, display devices (e.g., monitors), input/output device (e.g., mouse and keyboard). The software instructions may be written in any suitable programming language and may be designed to carry out specific tasks.

The integrated circuit fabrication system 900 enables interaction among the entities for the purpose of integrated circuit (IC) manufacturing, as well as the advanced processing control of the IC manufacturing. In an embodiment, the advanced processing control includes adjusting the processing conditions, settings, and/or recipes of one processing tool applicable to the relevant wafers according to the metrology results.

In another embodiment, the metrology results are measured from a subset of processed wafers according to an optimal sampling rate determined based on the process quality and/or product quality. In yet another embodiment, the metrology results are measured from chosen fields and points of the subset of processed wafers according to an optimal sampling field/point determined based on various characteristics of the process quality and/or product quality.

One of the capabilities provided by the IC fabrication system 900 may enable collaboration and information access in such areas as design, engineering, and processing, metrology, and advanced processing control. Another capability provided by the IC fabrication system 900 may integrate systems between facilities, such as between the metrology tool and the processing tool. Such integration enables facilities to coordinate their activities. For example, integrating the metrology tool and the processing tool may enable manufacturing information to be incorporated more efficiently into the fabrication process or the APC module, and may enable wafer data from the online or in site measurement with the metrology tool integrated in the associated processing tool.

FIG. 15 is a flowchart illustrating a method 1000 of fabricating a semiconductor device. The method 1000 includes a step 1010 to form a metal gate electrode layer over an active region. The metal gate electrode layer defines a recess.

The method 1000 includes a step 1020 to deposit a conductive layer over the metal gate electrode layer. The conductive layer partially fills the recess.

The method 1000 includes a step 1030 to deposit a silicon-containing material over the conductive layer. The silicon-containing material completely fills the recess.

The method 1000 includes a step 1040 to etch back the metal gate electrode layer and the conductive layer. The silicon-containing material has a substantially lower etching rate than the metal gate electrode layer and the conductive layer during the etching back.

The method 1000 includes a step 1050 to form a gate via over the conductive layer. The gate via vertically extends through the silicon-containing material.

In some embodiments, the depositing the conductive layer includes depositing a conductive material that contains tungsten and chlorine.

In some embodiments, the depositing the silicon-containing material includes depositing silicon, silicon oxide, or silicon nitride as the silicon-containing material.

In some embodiments, the metal gate electrode layer is a first metal gate electrode layer of a first transistor; the active region is a first active region of the first transistor; the forming the metal gate electrode layer further includes forming a second metal gate electrode layer over a second active region of a second transistor; the second metal gate electrode layer is formed without a recess; and the etching back simultaneous etches back the second metal gate electrode layer and the first metal gate electrode layer. In some embodiments, after the etching back, an upper surface of the first metal gate electrode layer and an upper surface of the second metal gate electrode layer have substantially similar vertical elevations.

It is understood that additional steps may be performed before, during, or after the steps 1010-1050. For example, in some embodiments, the conductive layer is a first portion of a conductive layer, and the method 1000 further the following steps that may be performed after the etching back but before the forming the gate via: depositing a second portion of the conductive layer over exposed upper surfaces of the metal gate electrode layer; and depositing a dielectric layer over the second portion of the conductive layer. In some embodiments, the depositing the dielectric layer includes depositing a dielectric material having a different material composition than the silicon-containing material. The method 1000 may also include the formation of other metal lines and vias of a multi-layer interconnect structure. For reasons of simplicity, these additional steps are not discussed in detail herein.

In summary, the present disclosure involves forming a silicon-containing material over a recess above a gate electrode of a long channel transistor (but not for a short channel transistor) before a metal gate etch-back process is performed. The silicon-containing material effectively reduces the lateral dimension of such a recess of the long channel transistor, such that when the metal gate electrode etch-back process is performed, the lateral dimension of the recess is on par with the lateral dimension of a recess above a metal gate electrode of a short channel transistor. The present disclosure also involves forming different segments of a conductive layer (e.g., a tungsten-containing layer) at different fabrication stages to serve as an electrical and physical interface between a gate via and the metal gate electrode for the long channel transistor. In some embodiments, a first segment of such a conductive layer is formed between the formation of the silicon-containing material, and a second segment of the conductive layer is formed after the metal gate electrode is etched back, but before the gate via is formed.

The unique fabrication process flow and the resulting IC device structure of the present disclosure offers advantages over conventional devices. It is understood, however, that no particular advantage is required, other embodiments may offer different advantages, and that not all advantages are necessarily disclosed herein. One advantage is the reduction of a loading effect. For example, as device sizes are scaled down in newer technology generations, the different sizes between the short channel transistors and long channel transistors may cause a loading effect when their metal gate electrodes are etched back. Due to such a loading effect, the metal gate electrode of the short channel transistor may be etched more than that of the long channel transistor, such that the short channel transistor has a significantly shorter metal gate electrode than the long channel transistor. This would have caused device performance degradations or decreased yields. The present disclosure overcomes the loading problem by implementing the silicon-containing material, which effectively reduces the size difference of the metal gate electrodes to be etched for both the short channel transistor and the long channel transistor during the etch-back process. As such, the metal gate electrodes of the short channel transistors and long channel transistors formed by the present disclosure may have substantially equal heights. Another advantage is low gate resistance. For example, by covering the entire upper surface of the metal gate electrode with different segments of a low-resistivity conductive layer (e.g., WCl₅), the electrical connection between the metal gate electrode and the gate via formed thereon can achieve a low resistance, thereby improving device performance such as speed or power consumption. Other advantages may include ease of fabrication and compatibility with existing fabrication processes.

The advanced lithography process, method, and materials described above can be used in many applications, including fin-type field effect transistors (FinFETs). For example, the fins may be patterned to produce a relatively close spacing between features, for which the above disclosure is well suited. In addition, spacers used in forming fins of FinFETs, also referred to as mandrels, can be processed according to the above disclosure. It is also understood that the various aspects of the present disclosure discussed above may apply to multi-channel devices such as Gate-All-Around (GAA) devices. To the extent that the present disclosure refers to a fin structure or FinFET devices, such discussions may apply equally to the GAA devices.

One aspect of the present disclosure pertains to a semiconductor device. The semiconductor device includes an active region. A metal gate electrode is disposed over the active region. A conductive layer is disposed over the metal gate electrode. A silicon-containing layer is disposed over a first portion of the conductive layer. A dielectric layer is disposed over a second portion of the conductive layer. A gate via vertically extends through the silicon-containing layer. The gate via is disposed over, and electrically coupled to, the metal gate electrode.

Another aspect of the present disclosure pertains to a semiconductor device. The semiconductor device includes a first transistor and a second transistor. The first transistor includes a first gate structure that contains a metal material, a first conductive layer disposed over the first gate structure, a silicon-containing structure and a first dielectric structure each disposed over the first conductive layer, and a first gate via disposed over the first conductive layer. The first gate via extends vertically through the silicon-containing structure. The second transistor includes: a second gate structure that contains the metal material, a second conductive layer disposed over the second gate structure, a second dielectric structure each disposed over the second conductive layer, and a second gate via disposed over the second conductive layer. The second gate via extends vertically through the second dielectric structure. The second gate structure has a shorter horizontal dimension than the first gate structure

Yet another aspect of the present disclosure pertains to a method of fabricating a semiconductor device. A metal gate electrode layer is formed over an active region. The metal gate electrode layer defines a recess. A conductive layer is deposited over the metal gate electrode layer. The conductive layer partially fills the recess. A silicon-containing material is deposited over the conductive layer. The silicon-containing material completely fills the recess. The metal gate electrode layer and the conductive layer are etched back. The silicon-containing material has a substantially lower etching rate than the metal gate electrode layer and the conductive layer during the etching back. A gate via is formed over the conductive layer. The gate via vertically extends through the silicon-containing material.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A device, comprising:
an active region;
a metal gate electrode disposed over the active region;
a conductive layer disposed over the metal gate electrode;
a silicon-containing layer disposed over a first portion of the conductive layer;
a dielectric layer disposed over a second portion of the conductive layer; and
a gate via vertically extending through the silicon-containing layer, wherein the gate via is disposed over, and electrically coupled to, the metal gate electrode.

2. The device of claim 1, wherein the silicon-containing layer and the dielectric layer have different material compositions.

3. The device of claim 1, wherein the silicon-containing layer contains silicon, silicon oxide, or silicon nitride.

4. The device of claim 1, wherein the conductive layer contains tungsten.

5. The device of claim 4, wherein the conductive layer further contains chlorine.

6. The device of claim 1, wherein:
an upper surface of the metal gate electrode defines a recess;
the first portion of the conductive layer is disposed in the recess; and
the second portion of the conductive layer is disposed outside of the recess.

7. The device of claim 1, further comprising gate spacers disposed on sidewalls of the metal gate electrode and the dielectric layer, wherein at least the dielectric layer is in direct physical contact with the gate spacers.

8. The device of claim 1, wherein:
the metal gate electrode is a first metal gate electrode of a first transistor;
the device further includes a second transistor having a shorter channel than the first transistor; the second transistor includes a second metal gate electrode; and
an uppermost surface of the first metal gate electrode has a substantially similar vertical elevation as an uppermost surface of the second metal gate electrode.

9. The device of claim 8, wherein the conductive layer is a first conductive layer, the dielectric layer is a first dielectric layer, and the gate via is a first gate via, and wherein the second transistor further includes:
a second conductive layer disposed over the second metal gate electrode, the second conductive layer and the first conductive layer having substantially similar material compositions;
a second dielectric layer disposed over the second conductive layer, the second dielectric layer and the first dielectric layer having substantially similar material compositions; and
a second gate via disposed over the second conductive layer, wherein the second gate via vertically extends through the second dielectric layer and is in direct physical contact with the second dielectric layer.

10. A device, comprising:
a first transistor that includes:
a first gate structure that contains a metal material;
a first conductive layer disposed over the first gate structure;
a silicon-containing structure and a first dielectric structure each disposed over the first conductive layer; and
a first gate via disposed over the first conductive layer, wherein the first gate via extends vertically through the silicon-containing structure; and
a second transistor that includes:
a second gate structure that contains the metal material, wherein the second gate structure has a shorter horizontal dimension than the first gate structure;
a second conductive layer disposed over the second gate structure;
a second dielectric structure each disposed over the second conductive layer; and
a second gate via disposed over the second conductive layer, wherein the second gate via extends vertically through the second dielectric structure.

11. The device of claim 10, wherein the silicon-containing structure and the first dielectric structure have different material compositions.

12. The device of claim 10, wherein:
the first gate structure has a more recessed upper surface than the second gate structure; or
the first conductive layer is more recessed than the second conductive layer.

13. The device of claim 10, wherein the first conductive layer and the second conductive layer each contains tungsten and chlorine.

14. A method, comprising:
forming a metal gate electrode layer over an active region, wherein the metal gate electrode layer defines a recess;
depositing a conductive layer over the metal gate electrode layer, wherein the conductive layer partially fills the recess;
depositing a silicon-containing material over the conductive layer, wherein the silicon-containing material completely fills the recess;
etching back the metal gate electrode layer and the conductive layer, wherein the silicon-containing material has a substantially lower etching rate than the metal gate electrode layer and the conductive layer during the etching back; and
forming a gate via over the conductive layer, wherein the gate via vertically extends through the silicon-containing material.

15. The method of claim 14, wherein the depositing the conductive layer includes depositing a conductive material that contains tungsten and chlorine.

16. The method of claim 14, wherein the depositing the silicon-containing material includes depositing silicon, silicon oxide, or silicon nitride as the silicon-containing material.

17. The method of claim 14, wherein the conductive layer is a first portion of a conductive layer, and wherein the method further comprises, after the etching back but before the forming the gate via:
depositing a second portion of the conductive layer over exposed upper surfaces of the metal gate electrode layer; and
depositing a dielectric layer over the second portion of the conductive layer.

18. The method of claim 17, wherein the depositing the dielectric layer includes depositing a dielectric material having a different material composition than the silicon-containing material.

19. The method of claim 14, wherein:
the metal gate electrode layer is a first metal gate electrode layer of a first transistor;
the active region is a first active region of the first transistor;
the forming the metal gate electrode layer further includes forming a second metal gate electrode layer over a second active region of a second transistor;
the second metal gate electrode layer is formed without a recess; and
the etching back simultaneous etches back the second metal gate electrode layer and the first metal gate electrode layer.

20. The method of claim 19, wherein after the etching back, an upper surface of the first metal gate electrode layer and an upper surface of the second metal gate electrode layer have substantially similar vertical elevations.
